(19) United States
(12) Patent Application Publication
(10) Pub. No.: US 2026/0082925 A1
(43) Pub. Date: Mar. 19, 2026

(54) SHIELDED INTERCONNECTION STRUCTURE, METHOD FOR FORMING THE SAME, AND SEMICONDUCTOR PACKAGE

(71) Applicant: JCET STATS ChipPAC Korea Limited, Incheon (KR)

(72) Inventors: SeungHyun LEE, Incheon (KR); HeeSoo LEE, Incheon (KR); HyeonChul LEE, Seoul (KR)

(21) Appl. No.: 19/322,715

(22) Filed: Sep. 9, 2025

(30) Foreign Application Priority Data
Sep. 14, 2024 (CN) 202411291909.7

(51) Int. Cl. H01L 23/552; H01L 21/48; H01L 23/498; H01L 23/538; H01L 25/16

(52) U.S. Cl. CPC H10W 42/20; H10W 70/095; H10W 70/611; H10W 90/401; H10W 90/701; H10W 90/00

(57) ABSTRACT

A shielded interconnection structure, a method for forming the shielded interconnection structure and a semiconductor package including the shielded interconnection structure are formed. The shielded interconnection structure may include: a dielectric base having a top surface, a bottom surface, and a lateral surface extending between the top surface and the bottom surface; a plurality of conductive pillars extending through the dielectric base; and a shielding layer having a lateral portion and a top portion formed as a whole, wherein the lateral portion of the shielding layer covers the lateral surface of the dielectric base, and the top portion of the shielding layer is formed on the top surface of the dielectric base to cover a first set of conductive pillars in the plurality of conductive pillars but expose a second set of conductive pillars in the plurality of conductive pillars.

### TECHNICAL FIELD

The present application generally relates to semiconductor technology, and more particularly, to a shielded interconnection structure, a method for forming the shielded interconnection structure, and a semiconductor package including the shielded interconnection structure.

### BACKGROUND OF THE INVENTION

In recent years, wireless communication modules are widely used in electronic devices such as cellular telephones, wireless networking devices and headsets. Wireless communication modules use electromagnetic waves (microwaves or radio waves), magnetic fields, and electric fields to enable wireless communication between devices. Typically, the wireless communication modules are packed into devices with various electronic modules for more functionalities. The wireless communication modules may be electrically connected with other modules in the device through conductive structures such as e-bar conductive structures. However, when signals emitted from the wireless communication modules are transmitted through the e-bar conductive structures, electromagnetic interferences (EMI) induced by the signals may disturb other electronic modules, especially those electronic modules disposed adjacent to the e-bar conductive structures, which may adversely affect the performance of these electronic modules.

Therefore, a need exists for an interconnection structure with better electromagnetic interference shielding in a semiconductor package.

### SUMMARY OF THE INVENTION

An objective of the present application is to provide a shielded interconnection structure with better electromagnetic interference shielding.

According to an aspect of the present application, a shielded interconnection structure is provided. The shielded interconnection structure may include: a dielectric base having a top surface, a bottom surface, and a lateral surface extending between the top surface and the bottom surface; a plurality of conductive pillars extending through the dielectric base; and a shielding layer having a lateral portion and a top portion formed as a whole, wherein the lateral portion of the shielding layer covers the lateral surface of the dielectric base, and the top portion of the shielding layer is formed on the top surface of the dielectric base to cover a first set of conductive pillars in the plurality of conductive pillars but expose a second set of conductive pillars in the plurality of conductive pillars.

According to another aspect of the present application, a method for forming a shielded interconnection structure is provided. The method may include: providing an interconnection strip, wherein the interconnection strip includes a plurality of interconnection structures, and each of the plurality of interconnection structures includes: a dielectric base having a top surface, a bottom surface, and a lateral surface extending between the top surface and the bottom surface; and a plurality of conductive pillars extending through the dielectric base; forming a trench in the interconnection strip to singulate the plurality of interconnection structures; and forming a shielding layer on each of the plurality of interconnection structures, wherein the shielding layer having a lateral portion and a top portion formed as a whole, the lateral portion of the shielding layer is formed in the trench to cover the lateral surface of the dielectric base, and the top portion of the shielding layer is formed on the top surface of the dielectric base to cover a first set of conductive pillars in the plurality of conductive pillars but expose a second set of conductive pillars in the plurality of conductive pillars.

According to another aspect of the present application, a semiconductor package is provided. The package may include: a first substrate; a second substrate disposed above the first substrate; at least one shielded interconnection structure mounted between the first substrate and the second substrate, wherein the shielded interconnection structure includes: a dielectric base having a top surface, a bottom surface, and a lateral surface extending between the top surface and the bottom surface; a plurality of conductive pillars extending through the dielectric base; and a shielding layer having a lateral portion and a top portion formed as a whole, wherein the lateral portion of the shielding layer covers the lateral surface of the dielectric base, and the top portion of the shielding layer is formed on the top surface of the dielectric base to cover a first set of conductive pillars in the plurality of conductive pillars but expose a second set of conductive pillars in the plurality of conductive pillars, wherein the first substrate and the second substrate are electrically connected with each other via the plurality of conductive pillars in the shielded interconnection structure.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a cross-sectional view illustrating a semiconductor package according to an embodiment of the present application.

FIG. 2A is a cross-sectional view illustrating a shielded interconnection structure according to an embodiment of the present application.

FIG. 2B is a top view of the shielded interconnection structure illustrated in FIG. 2A.

FIGS. 3A to 3K are cross-sectional views illustrating various steps of a method for forming a shielded interconnection structure according to an embodiment of the present application.

FIGS. 4A to 4E are cross-sectional views illustrating various steps of a method for forming a shielded interconnection structure according to another embodiment of the present application.

FIGS. 5A to 5H are cross-sectional views illustrating various steps of a method for forming a semiconductor package according to an embodiment of the present application.

FIGS. 6A to 6G are cross-sectional views illustrating various steps of a method for forming a semiconductor package according to another embodiment of the present application.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

To address the electromagnetic interference (EMI) issue as mentioned above, an interconnection structure with a shielding layer is provided. A lateral portion of the shielding layer covers a lateral surface of the interconnection structure, and a top portion of the shielding layer is electrically connected to at least one conductive pillar of the interconnection structure. The at least one conductive pillar may be connected with a reference voltage such as the ground, and thus EMI induced by signals transmitted through the interconnection structure can be reduced or eliminated, and an induced EMI current can be directed to the ground. Further, the lateral portion and the top portion of the shielding layer can be formed by a single deposition process, and thus a cost for forming the shielded interconnection structure is reduced.

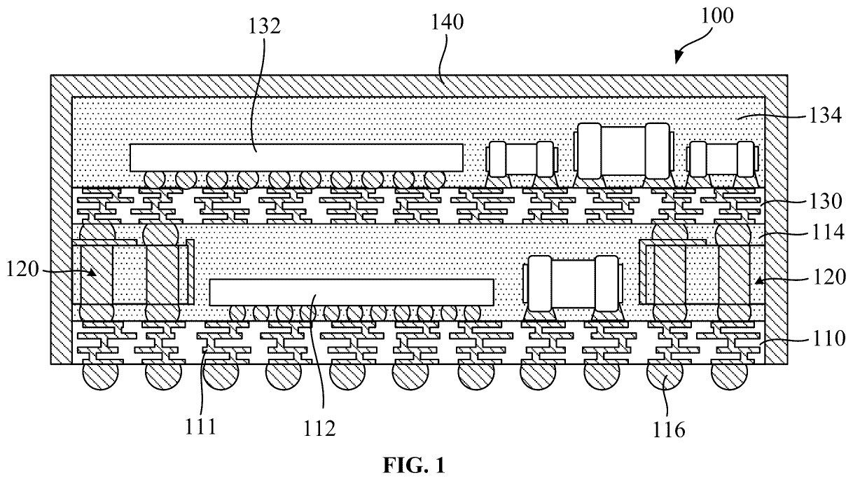

FIG. 1 illustrates a semiconductor package 100 according to an embodiment of the present application. The semiconductor package 100 may include one or more shielded interconnection structures according to the embodiment of the present application.

As shown in FIG. 1, the semiconductor package 100 has a multi-layer structure, i.e., multiple layers of electronic components are incorporated in the package to provide for a compact structure. The semiconductor package 100 may include a first substrate 110 with a plurality of interconnection wires 111 such as redistribution layers (RDLs) extending therethrough. The first substrate 110 may include a top surface and a bottom surface, which are opposite to each other. The top surface of the first substrate 110 may serve as a platform where electronic component(s) and interconnection structure(s) can be mounted. That is, the first substrate 110 can serve as a platform at a lower layer of the multi-layers structure of the semiconductor package 100. In some examples, the semiconductor package 100 may be a double-sided mounted (DSM) package, and accordingly, the bottom surface of the first substrate 110 may also serve as another platform where electronic component(s) may be mounted. Multiple sets of conductive pads may be formed on the top surface and/or bottom surface of the first substrate 110 for the mounting of the electronic components and the interconnection structure(s). It can be appreciated that the multiple sets of conductive pads may be exposed portions of the interconnection wires 111 formed within the first substrate 110.

At least one first electronic component 112 may be mounted on the top surface of the first substrate 110 via, for example, solder bumps. The first electronic components 112 may include any of a variety of types of semiconductor dice, semiconductor packages, or discrete devices. In some embodiments, the first electronic component 112 may include an ultra-wide bandwidth (UWB) communication integrated circuit chip. The UWB communication integrated circuit chip may be sensitive to electromagnetic interferences when in an operation state. In some other embodiments, the first electronic component 112 may also include a high-precision sensor, a semiconductor chip, a resistor or a capacitor, which should also be protected from electromagnetic interference when in operation.

The semiconductor package 100 includes a second substrate 130 with embedded interconnect wires. The second substrate 130 is disposed above the first substrate 110, and also includes a top surface and a bottom surface, which are opposite to each other. The top surface of the second substrate 130 may also serve as a platform where electronic component(s) can be mounted. That is, the second substrate 130 serves as a platform at an upper layer of the multi-layers structure of the semiconductor package 100. It can be appreciated that additional layers of substrates may be integrated within the semiconductor package 100.

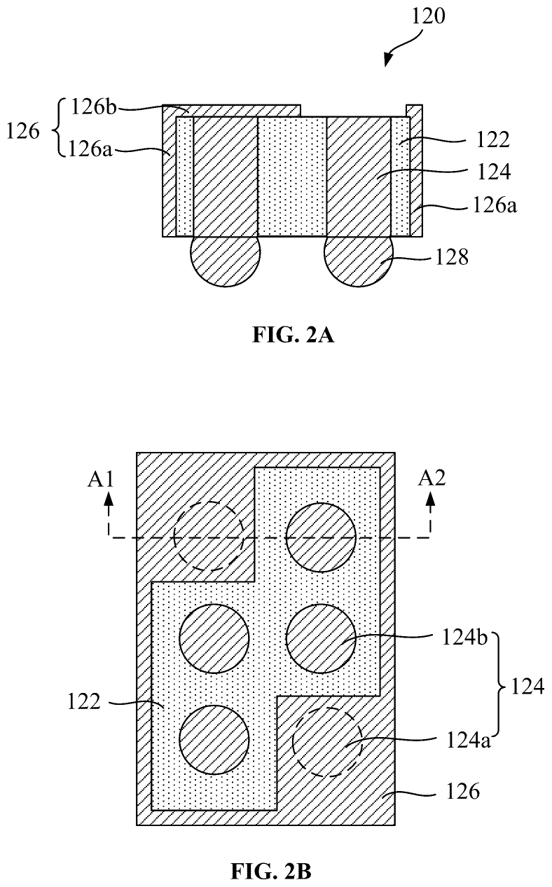

As shown in FIG. 1, the semiconductor package 100 further includes at least one shielded interconnection structure 120 mounted between the first substrate 110 and the second substrate 130, so as to electrically connect them with each other. Referring to FIG. 2A and FIG. 2B, an enlarged cross-sectional view and a top view of the shielded interconnection structure 120 shown in FIG. 1 are illustrated. The shielded interconnection structure 120 may include a dielectric base 122, a plurality of conductive pillars 124 extending through the dielectric base 122, and a shielding layer 126 formed on a lateral surface and at least a portion of a top surface of the dielectric base 122. The conductive pillars 124 may provide various signal/power paths which extend generally vertically between the two substrates 110 and 130 in the semiconductor package 100. In some embodiments, the shielded interconnection structure 120 may be mounted onto the first substrate 110 and the second substrate 130 via solder bumps or using other suitable surface mounting techniques.

Further, at least one second electronic component 132 may be mounted on the top surface of the second substrate 130 via, for example, solder bumps. In some examples, the second electronic component 132 may be electrically connected with the shielded interconnection structure 120 through the solder bumps and interconnection wires within the second substrate 130. Further, the second electronic component 132 may be electrically connected with the first substrate 110 and other electronic components through the shielded interconnection structure 120. The second electronic component 132 may include any of a variety of types of semiconductor dice, semiconductor packages, or discrete devices. In some embodiments, the second electronic component 132 may include a wireless communication device which requires electromagnetic communication with the external space to emit and receive wireless signals, such as a WiFi communication device or a Bluetooth communication device. The wireless communication device may emit and receive signals in forms of electromagnetic waves.

In the example shown in FIG. 1, when the wireless communication device is in operation, it may receive signals from or transmit signals to other electronic modules through the interconnect wires within the second substrate 130 and the conductive pillars 124 within the shielded interconnection structure 120 for required functionality. With the shielding layer 126, electromagnetic interferences induced by the signals transmitted through the conductive pillars 124 of the shielded interconnection structure 120 may be prevented from propagating outside of the shielded interconnection structure 120 and from disturbing the first electronic component 112, thereby enhancing performance of the first electronic component 112 disposed around the shielded interconnection structure 120.

Continuing referring to FIG. 1, the semiconductor package 100 further includes a first encapsulant 114 and a second encapsulant 134. The first encapsulant 114 is formed on the top surface of the first substrate 110 and encapsulates the first electronic component 112 and the shielded interconnection structure 120, and the second encapsulant 134 is formed on the top surface of the second substrate 130 and encapsulates the second electronic component 132. The first encapsulant 114 and the second encapsulant 134 can provide mechanical protection, environmental protection, and a hermetic seal for the semiconductor package 100, and may be made from, for example, an epoxy molding compound (EMC), a polymide compound, or any other suitable dielectric materials. A plurality solder bumps 116 may be further formed on the bottom surface of the first substrate 110 for mounting the semiconductor package 100 onto an external device or substrate, such as a printed circuit board (PCB).

Furthermore, the semiconductor package 100 may include an outer shielding layer 140. The outer shielding layer 140 may cover the lateral surfaces of the first substrate 110, the first encapsulant 114, the second substrate 130 and the second encapsulant 134, and a top surface of the second encapsulant 134 to further protect the semiconductor package 100 from electromagnetic interferences.

It can be appreciated the semiconductor package 100 shown in FIG. 1 is exemplary and the present application is not limited thereto. In some examples, there may be one or more than two shielded interconnection structures mounted between the first substrate and the second substrate, and there may other types of substrates and electronic components integrated in the semiconductor package.

In the following, the shielded interconnection structure 120 will be described with reference to FIG. 2A and FIG. 2B in more details. In particular, FIG. 2B illustrates the top view of the shielded interconnection structure 120 shown in FIG. 1, and FIG. 2A is the cross-sectional view of the shielded interconnection structure 120 along a line A1A2 shown in FIG. 2B.

The shielded interconnection structure 120 includes a dielectric base 122. The dielectric base 122 may include an epoxy molding compound. However, the present application is not limited thereto. In other examples, the dielectric base 122 may include other dielectric materials such as an insulative polymeric material or composite, or silicon dioxide. The dielectric base 122 includes a top surface and a bottom surface, and a lateral surface extending between the top surface and the bottom surface. A plurality of conductive pillars 124 may extend from the top surface to the bottom surface of the dielectric base 122. The conductive pillars 124 may be copper pins. However, the present application is not limited thereto. In other examples, the conductive pillars 124 may include aluminum, nickel-plated copper, nickel-plated aluminum, or other materials with a high conductivity. The plurality of conductive pillars 124 may include a first set of conductive pillars 124a (indicated by dashed-line circles in FIG. 2B) and a second set of conductive pillars 124b (indicated by solid-line circles in FIG. 2B). The first set of conductive pillars 124a may be connected with a reference voltage, e.g., to a ground node/line. The second set of conductive pillars 124b may serve as an electrical connection or a signal transmitting channel between the second electronic component 132 on the second substrate 130 and the first substrate 110 shown in FIG. 2A.

Furthermore, the shielded interconnection structure 120 includes a shielding layer 126 formed on the lateral surface and at least a portion of the top surface of the dielectric base 122. For example, the shielding layer 126 may include copper, aluminum, conducting polymers, or any other suitable material for EMI shielding. Referring to FIG. 2A and FIG. 2B, the shielding layer 126 may include a lateral portion 126a and a top portion 126b. The lateral portion 126a and the top portion 126b may be formed as a whole, for example, using a single batch of manufacturing process(es). The lateral portion 126a may cover the lateral surface of the dielectric base 122, and the top portion 126b may be formed on the top surface of the dielectric base 122 to cover the first set of conductive pillars 124a but expose the second set of conductive pillars 124b, such that the shielding layer 126 can be electrically connected to the reference voltage (e.g., a ground node/line) via the first set of conductive pillars 124a. In this way, an induced EMI current can be directed to the ground, and EMI can be blocked from propagating into an external space of the shielded interconnection structure 120. The shielded interconnection structure 120 may further include a plurality of conductive bumps 128 (e.g., solder balls) on the bottom surface of the dielectric base 122, and the plurality of conductive bumps 128 may be electrically connected with the plurality of conductive pillars 124 respectively for mounting the shielded interconnection structure 120 onto external electronic modules.

FIG. 2B shows a layout or pattern of the first set of conductive pillars 124a and the second set of conductive pillars 124b. As shown in FIG. 2B, the first set of conductive pillars 124a and the second set of conductive pillars 124b may have the same pillar size, and may be formed of the same material and using the same fabrication process. The dielectric base 122 may have a section of a cuboid shape, and includes four edges together forming the lateral surface of the dielectric base 122. In the embodiment shown in FIG. 2B, the first set of conductive pillars 124a includes two conductive pillars each disposed at a corner of the dielectric base 122, which is adjacent to two edges of the dielectric base 122. In this way, it is more convenient to connect the first set of conductive pillars 124a with the shielding layer 126 to provide a reference voltage. The second set of conductive pillars 124b includes four conductive pillars, which are exposed from the top portion 126b of the shielding layer 126, such that the second set of conductive pillars 124b can be electrically connected with the second substrate 130 for signal transmission.

However, the present application is not limited to the example shown in FIG. 2B. In some other embodiments, the first set of conductive pillars 124a and the second set of conductive pillars 124b each may include more or less conductive pillars and may be disposed at other positions of the dielectric base 122, and one or more conductive pillars of the second set of conductive pillars 124b can also be electrically connected to the reference voltage.

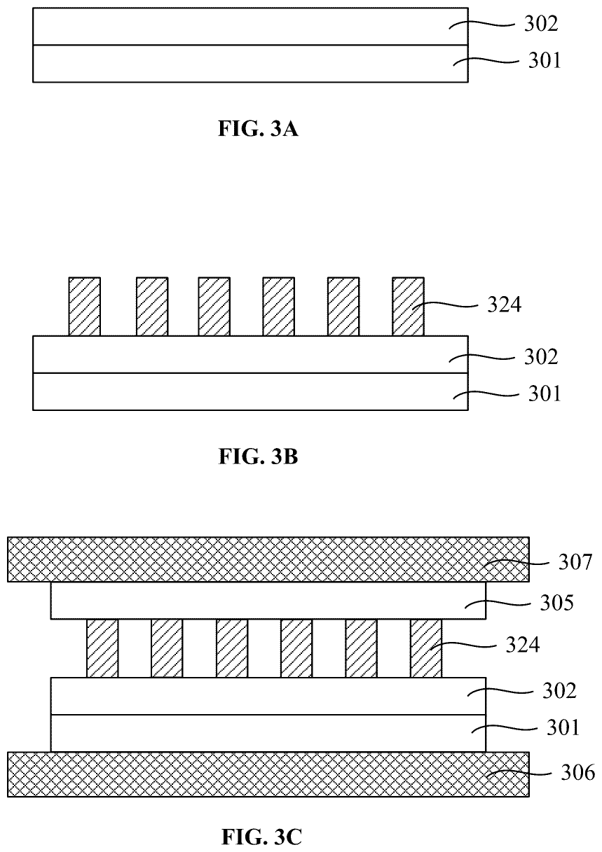

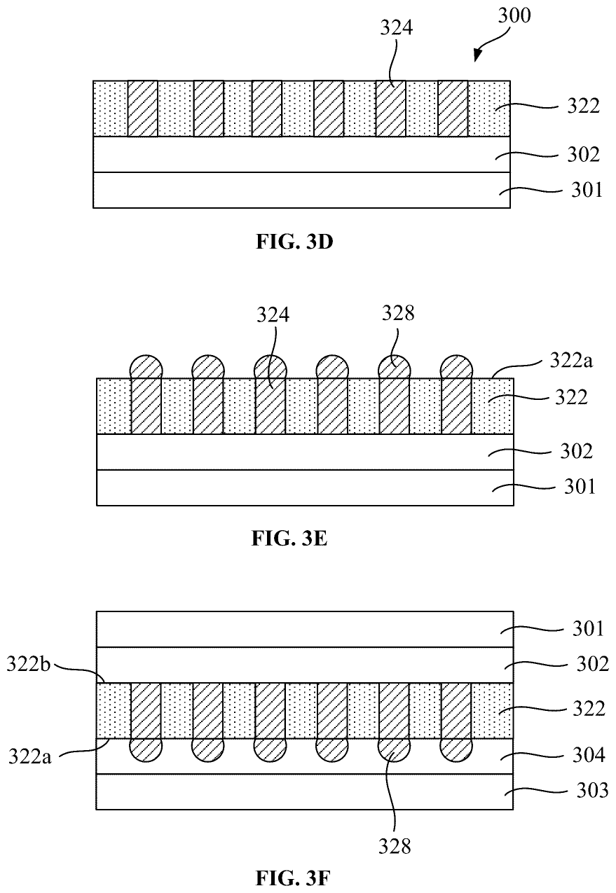

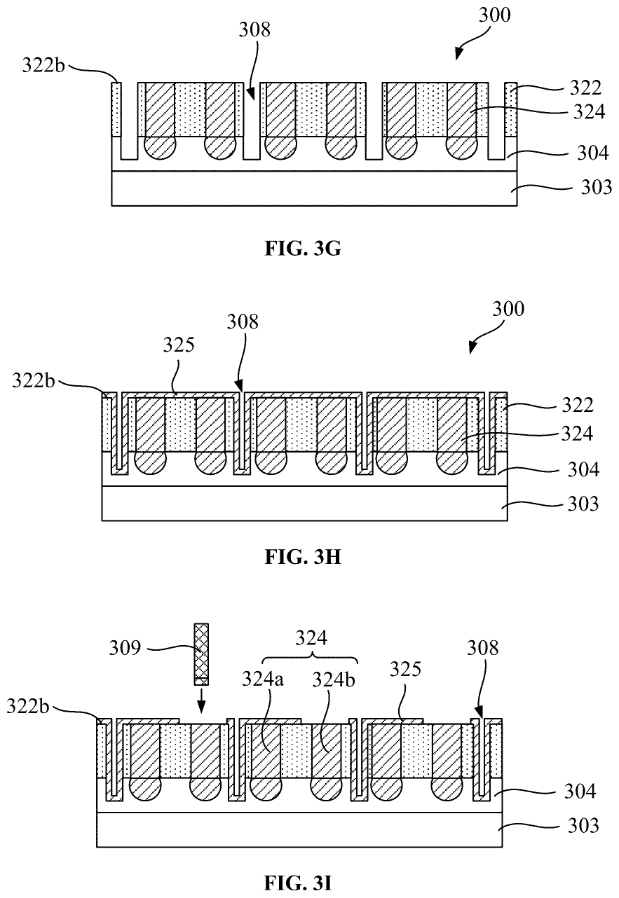

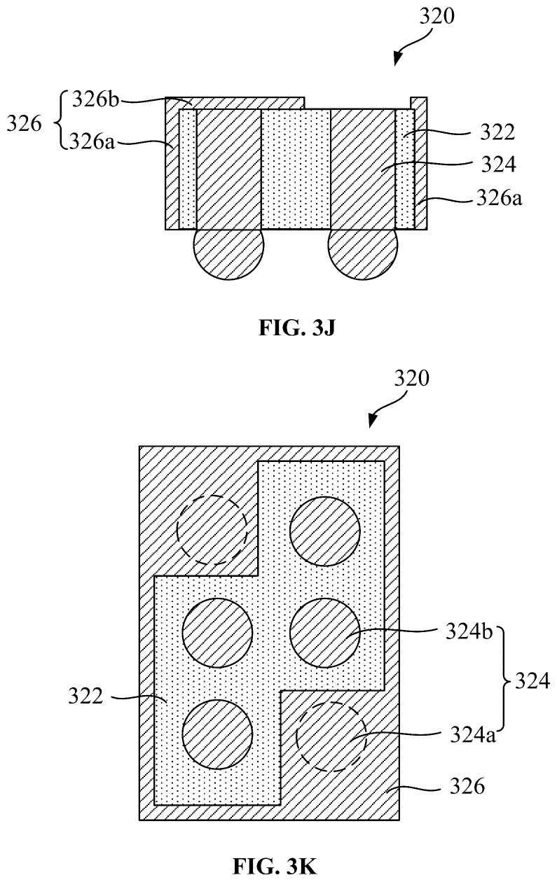

FIGS. 3A to 3K illustrate various steps of a method for forming a shielded interconnection structure according to an embodiment of the present application. For example, the method can be used to form the shielded interconnection structure 120 illustrated in FIGS. 2A and 2B.

Referring to FIG. 3A, a first carrier 301 is provided, and a first adhesive film 302 is attached onto a top surface of the first carrier 301. The first carrier 301 may be a flat sheet of an organic material, glass, silicon, polymer, or any other materials suitable to provide physical support for the shielded interconnection structure to be formed during the manufacturing process. The first adhesive film 302 may be a double-sided tape. For example, the first adhesive film 302 may be an ultraviolet (UV) sensitive tape, which may be hardened after irradiation by UV light with a certain wavelength range. In another example, the first adhesive film 302 may include adhesive materials such as adhesive polymer, plastic, ceramics or the like.

Referring to FIG. 3B, multiple conductive pillars 324 are attached on the first carrier 301 via the first adhesive film 304. In some embodiments, the conductive pillars 324 may be copper pins. However, the present application is not limited thereto. In other embodiments, the conductive pillars 324 may include aluminum, nickel-plated copper, nickel-plated aluminum, or other materials with a high conductivity. In some embodiments, the conductive pillars 324 may be arranged in an array, but the present application is not limited thereto.

Referring to FIG. 3C and FIG. 3D, the conductive pillars 324 may be encapsulated with a molding material to form a dielectric base 322. In some embodiments, a film assisted molding (FAM) technique may be used to form the dielectric base 322. For example, a molding apparatus with a bottom chase 306 and a top chase 307 may be provided. The first carrier 301 may be disposed on the bottom chase 306 with the conductive pillars 324 facing upwards. A film 305 may be attached on an inner surface of the top chase 307. Then, the top chase 307 is placed over the first carrier 301 to form a molding chamber. The film 305 is sandwiched between the top chase and the conductive pillars 324. Afterwards, an encapsulant material such as an epoxy molding compound (EMC) is injected into the molding chamber. After the epoxy molding compound is solidified, the first carrier 301 is unloaded from the bottom chase 306 and the top chase 307, and the film 305 is also detached to expose top surfaces of the conductive pillars 324. In some cases, the film 305 may include a Teflon-based material, and thus can be easily released from the conductive pillars 324. Accordingly, the top surfaces of the conductive pillars 324 can be kept clear of sticky molding compound. Then, as shown in FIG. 3D, an interconnection strip 300 is formed. The interconnection strip 300 can be singulated to obtain a plurality of interconnection structures, and each interconnection structure may include a dielectric base 322 and a plurality of conductive pillars 324 extending through the dielectric base 322.

Referring to FIG. 3E, multiple conductive bumps 328 may be formed on a first surface 322a of the dielectric base 322 to electrically connect with the multiple conductive pillars 324 respectively. The conductive bumps 328 may be formed using a suitable mounting or bonding process. In an example, the conductive bumps 328 may be solder balls, and are formed by reflowing solder materials. In some examples, each of the conductive bumps 328 may be a stud bump, a micro bump, or other suitable electrical interconnects.

Referring to FIG. 3F, the structure shown in FIG. 3E is flipped with the first surface 322a of the dielectric base 322 facing downwards. Then, the first surface 322a of the dielectric base 322 is attached to a second carrier 303 via a second adhesive film 304. The second carrier 303 and the second adhesive film 304 may be similar to the first carrier 301 and the first adhesive film 302 respectively, and will not be elaborated herein. Afterwards, the first carrier 301 and the first adhesive film 302 are removed to expose a second surface 322b of the dielectric base 322. The first surface 322a and the second surface 322b are opposite to each other, and may also be referred to as the bottom surface 322a and the top surface 322b of the dielectric base 322 hereinafter.

Referring to FIG. 3G, a trench 308 is formed in the interconnection strip 300 for subsequent singulation of the plurality of interconnection structures. The trench 308 is at a singulation channel of the interconnection strip 300. In some examples, a laser cutting tool may be used to form the trench 308 in the interconnection strip 300. In some other examples, a saw blade may be used to form the trench 308 in the interconnection strip 300.

Referring to FIG. 3H, a shielding material 325 is deposited on the interconnection strip 300 to cover inner surfaces of the trench 308 and the top surfaces 322b of the dielectric base 322. The deposition of the shielding material 325 may be conducted using a sputtering process such as an ion-beam sputtering technique, a reactive sputtering technique, a high-target-utilization sputtering technique, a gas flow sputtering technique, etc., or any other suitable deposition processes that may form a generally conformal shielding layer. The shielding material 325 may include copper, aluminum, conducting polymers, or any other suitable material for EMI shielding.

Referring to both FIG. 3H and FIG. 3I, a portion of the shielding material 325 on the top surface 322b of the dielectric base 322 is removed to expose a set of conductive pillars 324. For example, a laser ablation tool 309 may be employed to remove the portion of the shielding material 325. However, the present application is not limited thereto. In some other examples, an etching process or any other processes known in the art may be used to remove the portion of the shielding material 325. In some examples, after the portion of the shielding material 325 is removed, a cleaning process for removing residuals may further be performed. As shown in FIG. 3I, the conductive pillars 324 still covered by the shielding material 325 may form a first set of conductive pillars 324a which are used for connecting with a reference voltage, and the conductive pillars 324 exposed from the shielding material 325 may form a second set of conductive pillars 324b which are used for signal transmission.

Afterwards, referring to FIG. 3I and FIG. 3J, the plurality of interconnection structures 320 may be detached from the second carrier 303 by releasing the second adhesive film 304. As the plurality of interconnection structures 320 have been separated by the trenches 308, they can be singulated from each other after being detached from the second carrier 303.

At last, referring to FIG. 3J and FIG. 3K, a cross-sectional view and a top view of an individual shielded interconnection structure 320 are illustrated respectively. The shielded interconnection structure 320 includes a dielectric base 322, a plurality of conductive pillars 324 extending through the dielectric base 322, and a shielding layer 326. The shielding layer 326 has a lateral portion 326a and a top portion 326b formed as a whole. The lateral portion 326a covers a lateral surface of the dielectric base 322, and the top portion 326b is formed on the top surface of the dielectric base 322 to cover a first set of conductive pillars 324a in the plurality of conductive pillars 324 but expose a second set of conductive pillars 324b in the plurality of conductive pillars 324. With the above processes, the method for forming the shielded interconnection structure 320 can be conducted in a mass production for lower cost and higher efficiency.

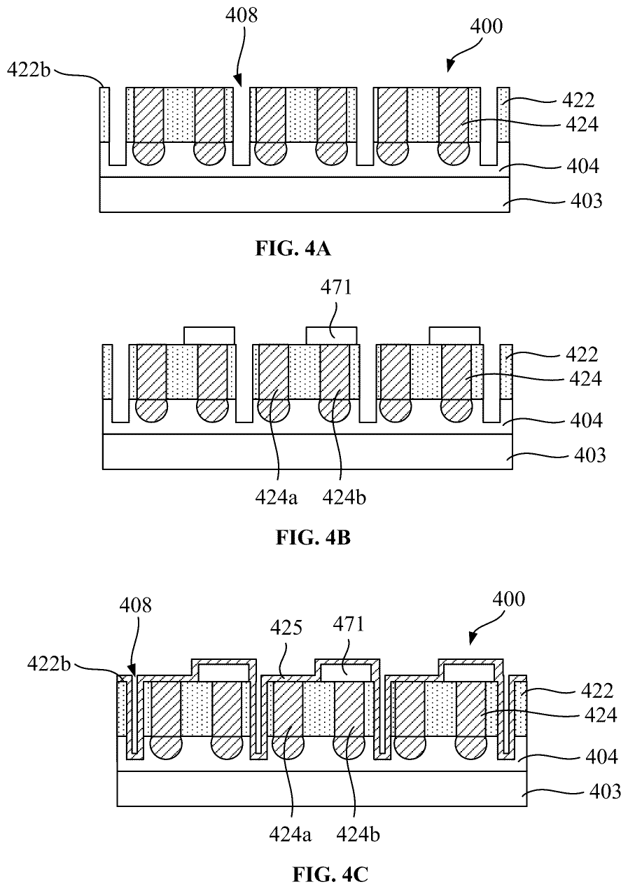

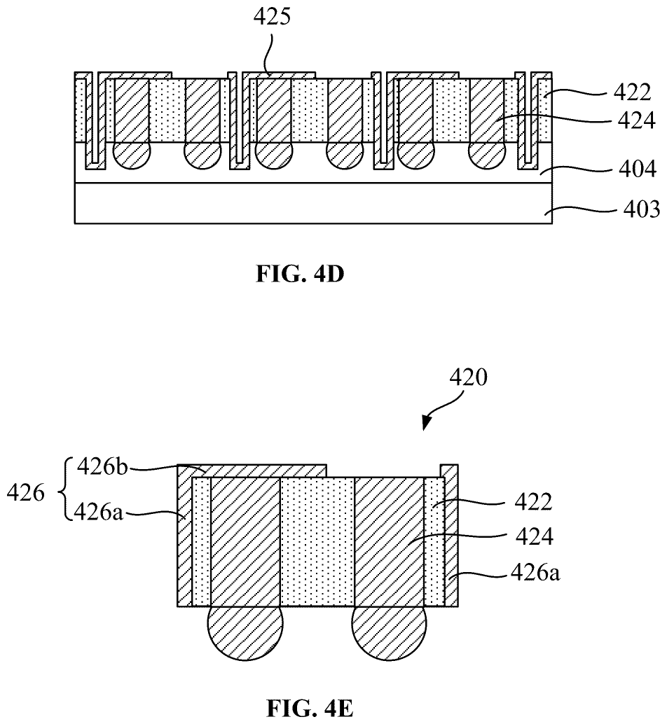

FIGS. 4A to 4E illustrate various steps of a method for forming a shielded interconnection structure according to another embodiment of the present application. For example, the method can be used to form the shielded interconnection structure 120 illustrated in FIGS. 2A and 2B.

Referring to FIG. 4A, an interconnection strip 400 is provided. The interconnection strip 400 may include a plurality of interconnection structures, each of which includes a dielectric base 422 and a plurality of conductive pillars 424 extending through the dielectric base 422. A trench 408 is formed in the interconnection strip 400 to singulate the plurality of interconnection structures from each other. The interconnection strip 400 may be attached on a carrier 403 via an adhesive film 404. The interconnection strip 400 may have a same or similar structure and configuration as the interconnection strip 300 shown in FIG. 3G, and will not be elaborated herein.

Referring to FIG. 4B, a patterned mask 471 may be formed on a top surface of the dielectric base 422. The patterned mask 471 may have a plurality of openings, which exposes a first set of conductive pillars 424a but covers a second set of conductive pillars 424b. The patterned mask 471 may be a stencil, a masking tape, a photoresist mask, etc.

Referring to FIG. 4C, a shielding material 425 is deposited on the interconnection strip 400 to cover inner surfaces of the trench 408, the top surface 422b of the dielectric base 422, and a lateral and top surface of the patterned mask 471. Thus, the shielding material 425 may contact the first set of conductive pillars 424a, but is separated from the second set of conductive pillars 424b by the patterned mask 471. The deposition of the shielding material 425 may be conducted by a sputtering process such as an ion-beam sputtering technique, a reactive sputtering technique, a high-target-utilization sputtering technique, a gas flow sputtering technique, etc., or any other suitable deposition processes that may form a generally conformal shielding layer. The shielding material 425 may include copper, aluminum, conducting polymers, or any other suitable material for EMI shielding.

Referring to FIG. 4C and FIG. 4D, the patterned mask 471 together with the shielding material 425 formed thereon may be removed from the top surface of the dielectric base 422, to expose the second set of conductive pillars 424b.

Afterwards, referring to FIG. 4D and FIG. 4E, the plurality of interconnection structures 420 may be detached from the carrier 403 by releasing the adhesive film 404. As the plurality of interconnection structures 420 have been separated by the trench 408, they can be singulated from each other after being detached from the second carrier 403. As shown in FIG. 4E, an individual shielded interconnection structure 420 includes a dielectric base 422, a plurality of conductive pillars 424 extending through the dielectric base 422, and a shielding layer 426. The shielding layer 426 has a lateral portion 426a and a top portion 426b formed as a whole. The lateral portion 426a covers a lateral surface of the dielectric base 422, and the top portion 426b is formed on the top surface of the dielectric base 422 to cover a first set of conductive pillars 424a but expose a second set of conductive pillars 424b.

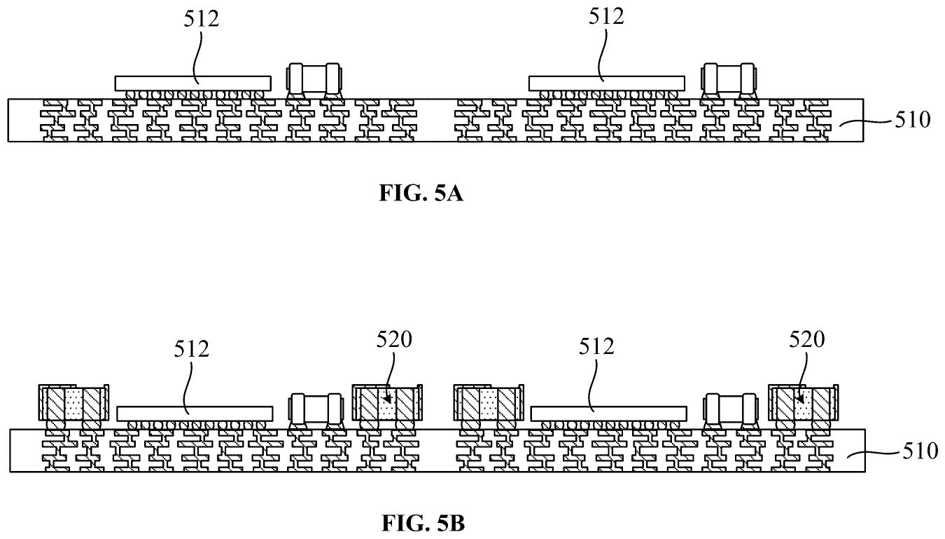

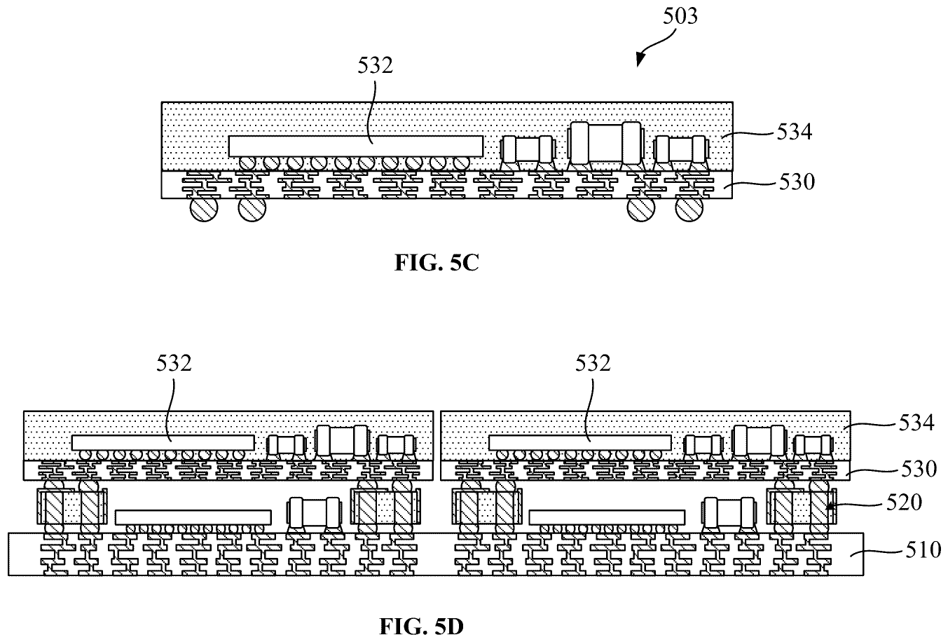

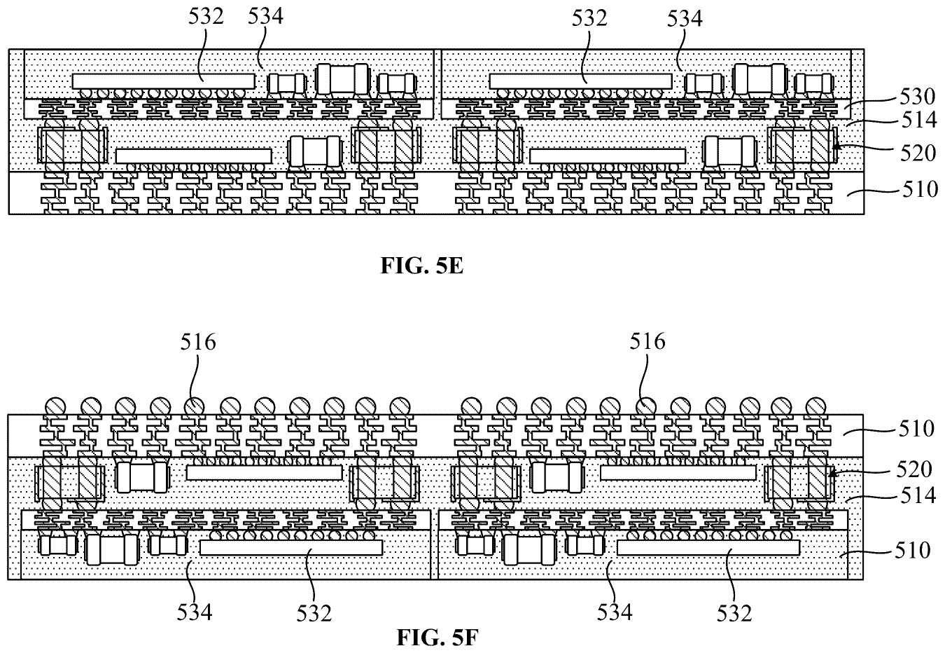

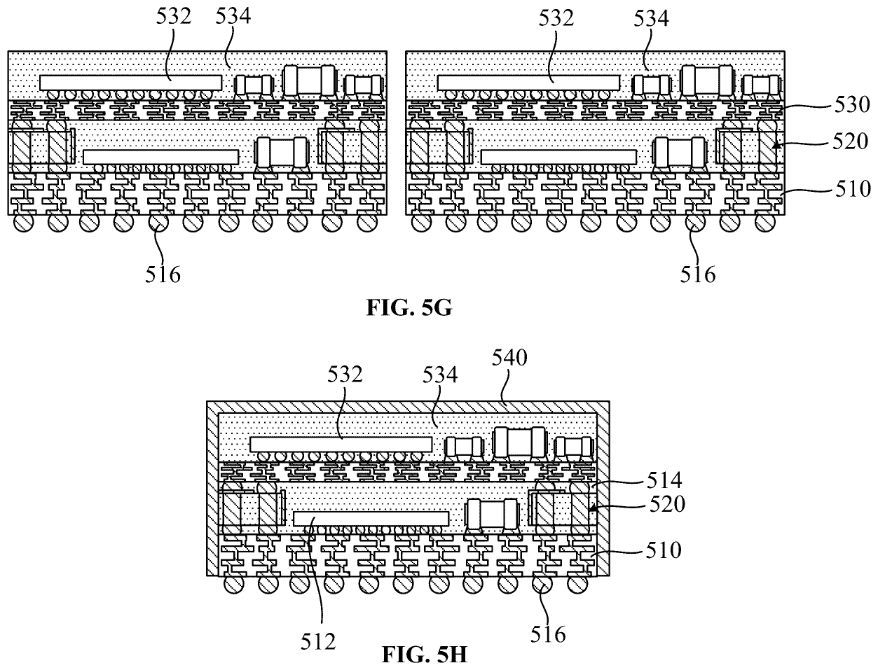

FIGS. 5A to 5H illustrate various steps of a method for forming a semiconductor package according to an embodiment of the present application. For example, the method can be used to form the semiconductor package 100 illustrated in FIG. 1.

Referring to FIG. 5A, a plurality of first substrates 510 may be provided in a substrate strip. The substrate strip may include a plurality of linkage portions, each of which is positioned between two adjacent first substrates 510, thus connecting the plurality of first substrates 510 as the substrate strip. In this embodiment, each of the first substrates 510 may have the same or similar structures. For simplicity, the following steps of forming the semiconductor package may be illustrated with reference to one of the first substrates 510. It can be appreciated that a plurality of electronic package assemblies may be formed using the same processing on the plurality of first substrates 510. As shown in FIG. 5A, at least one first electronic component 512 is mounted on a top surface of the first substrate 510. The first electronic component 512 may include an ultra-wide bandwidth (UWB) communication integrated circuit chip, or other electronic components which should be protected from electromagnetic interference when in operation.

Next, referring to FIG. 5B, at least one shielded interconnection structure 520 is mounted on the top surface of the first substrate 510 via, for example, solder bumps. The shielded interconnection structure 520 may have the same or similar structure and configuration as the shielded interconnection structure 120 shown in FIG. 2A and FIG. 2B, and will not be elaborated herein. Next, a plurality of sub-packages 503 as shown in FIG. 5C are provided. The sub-package 503 may include a second substrate 530, at least one second electronic component 532 mounted on a top surface of the second substrate 530, and a second encapsulant 534 formed on the top surface of the second substrate 530 and encapsulating the second electronic component 532. The second electronic component 532 may include a wireless communication device. Next, as shown in FIG. 5D, the second substrate 530 may be mounted on a top surface of the shielded interconnection structure 520, and electrically connected with the shielded interconnection structure 520 via, for example, solder bumps.

Afterwards, referring to FIG. 5E, a first encapsulant 514 is formed on the top surface of the first substrate 510 to fill gaps between the first substrate 510 and the second substrate 530 and encapsulate the first electronic component 512, the shielded interconnection structure 520, and the sub-package 503 including the second substrate 530, the second electronic component 532 and the second encapsulant 534. In some cases, a top surface of the first encapsulant 514 may be grinded to expose a top surface of the second encapsulant 534. Next, as shown in FIG. 5F, the structure shown in FIG. 5E is flipped with a bottom surface of the first substrate 510 facing upwards, and a plurality of solder bumps 516 may be formed on the bottom surface of the first substrate 510 for mounting of the semiconductor package onto an external electronic module.

Afterwards, as shown in FIG. 5G, the substrate strip may be singulated to form a plurality of individual electronic packages. In the example shown in FIG. 5G, during the singulation process, an outer lateral portion of the shielding layer of the shielded interconnect structure 520 (i.e., a portion adjacent to a singulation channel) may be removed, and a top portion of the shielding layer of the shielded interconnect structure 520 may be exposed from the encapsulant. However, the present application is not limited thereto. In some other embodiments, the shielded interconnect structure 520 is still encapsulated by the encapsulant after the singulation process. Then, as shown in FIG. 5H, an outer shielding layer 540 may be formed on the lateral surfaces of the first substrate 510, the first encapsulant 514, the second substrate 530 and the second encapsulant 534, and a top surface of the second encapsulant 534 to further protect the semiconductor package from electromagnetic interferences. In some examples, if the top portion of the shielding layer of the shielded interconnect structure 520 is exposed from the first encapsulant 514, the outer shielding layer 540 may be electrically connected with the shielding layer of the shielded interconnect structure 520.

In the above embodiment, the second encapsulant 534 is first formed in the sub-package 503, and the sub-package 503 is mounted on the shielded interconnection structure 520. However, the present application is not limited thereto. In other embodiments, a sub-package without the second encapsulant may be provided, and after the sub-package is mounted on the shielded interconnection structure, a molding process may be used to form the first encapsulant and the second encapsulant simultaneously.

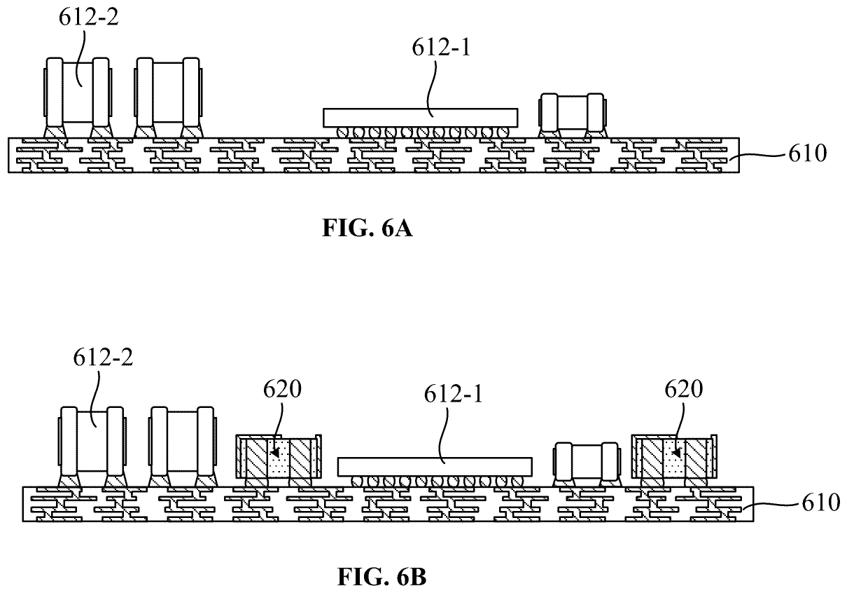

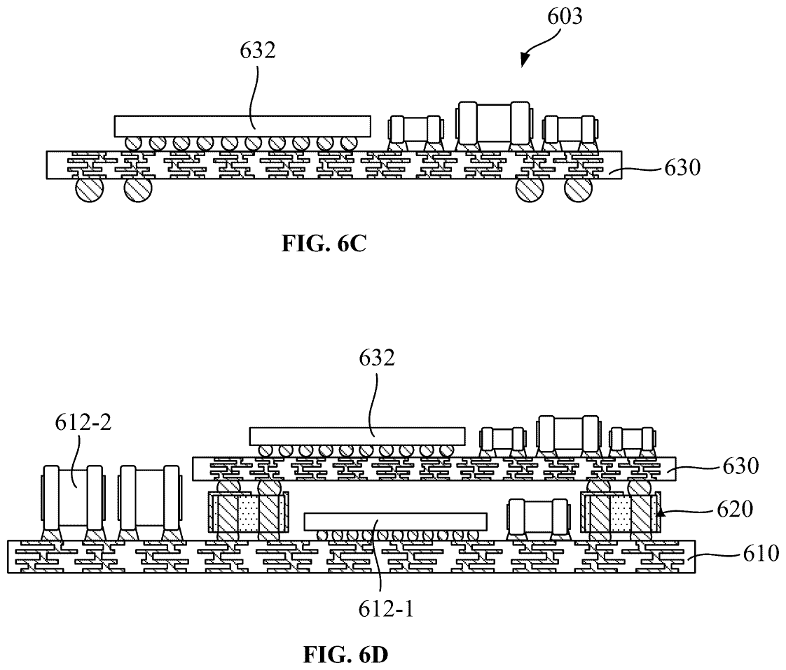

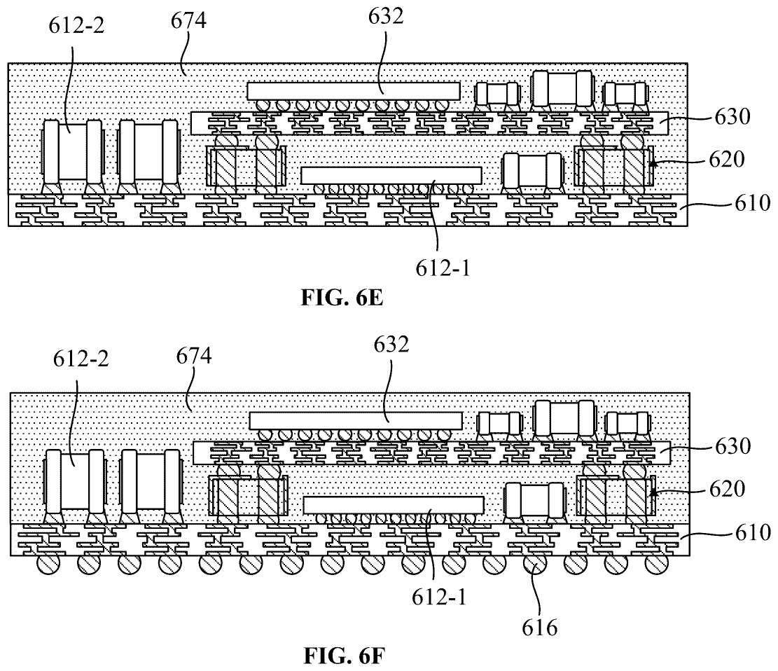

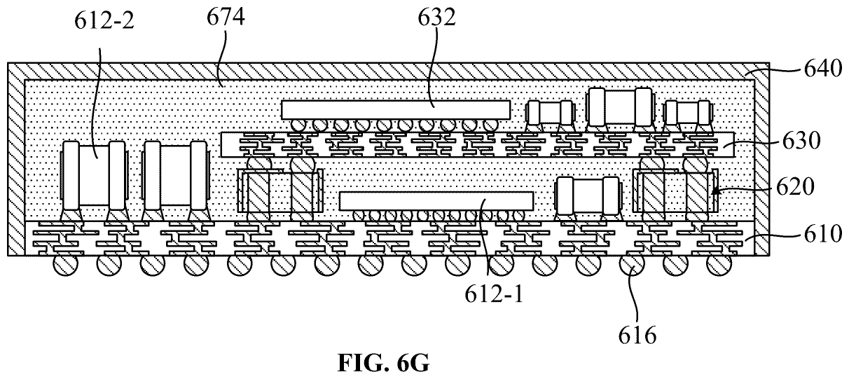

FIGS. 6A to 6G illustrate various steps of a method for forming a semiconductor package according to another embodiment of the present application.

Referring to FIG. 6A, a first substrate 610 is provided, and a plurality of first electronic components 612-1 and 612-2 are mounted on a top surface of the first substrate 610. The plurality of first electronic components 612-1 and 612-2 may have different thicknesses. For example, the electronic components 612-2 may be much thicker than the electronic components 612-1.

Referring to FIG. 6B, at least one shielded interconnection structure 620 is mounted on the top surface of the first substrate 610 via, for example, solder bumps. The shielded interconnection structure 620 may have the same or similar structure and configuration as the shielded interconnection structure 120 shown in FIG. 2A and FIG. 2B, and will not be elaborated herein.

Referring to FIG. 6C, a sub-package 603 is provided. The sub-package 603 may include a second substrate 630, and at least one second electronic component 632 mounted on a top surface of the second substrate 630. The second electronic component 632 may include a wireless communication device. Next, as shown in FIG. 6D, the second substrate 630 may be mounted on a top surface of the shielded interconnection structure 620, and electrically connected with the shielded interconnection structure 620 via, for example, solder bumps. The second substrate 630 may have a smaller footprint than the first substrate 610, and thus may cover the thinner electronic components 612-1 and expose the thicker electronic components 612-2, thereby forming a compact structure.

Next, referring to FIG. 6E, an encapsulant 674 is formed to encapsulate the first electronic components 612-1 and 612-2, the shielded interconnection structure 620, the second substrate 630 and the second electronic component 632. The encapsulant 674 may have a first portion to encapsulate the first electronic components 612-1 and 612-2 mounted on the first substrate 610, and a second portion to encapsulate the second electronic components 632 mounted on the second substrate 630.

Next, as shown in FIG. 6F, a plurality of solder bumps 616 may be formed on the bottom surface of the first substrate 610 for mounting of the semiconductor package onto an external electronic module. At last, referring to FIG. 6G, an outer shielding layer 640 may be formed on the lateral surfaces of the first substrate 610, and the lateral and top surfaces of the encapsulant 674 to further protect the semiconductor package from electromagnetic interferences.

In the above embodiment, the sub-package 603 is provided without an encapsulant, and is directly mounted on the shielded interconnection structure 620. However, the present application is not limited thereto. In other embodiments, an encapsulant may be first formed on the second substrate, and then the sub-package with the encapsulant is mounted on the shielded interconnection structure.

The discussion herein included numerous illustrative figures that showed various portions of a shielded interconnection structure or a semiconductor package and a method for forming the same. For illustrative clarity, such figures did not show all aspects of each exemplary semiconductor package assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A shielded interconnection structure, comprising:
a dielectric base having a top surface, a bottom surface, and a lateral surface extending between the top surface and the bottom surface;
a plurality of conductive pillars extending through the dielectric base; and
a shielding layer having a lateral portion and a top portion formed as a whole, wherein the lateral portion of the shielding layer covers the lateral surface of the dielectric base, and the top portion of the shielding layer is formed on the top surface of the dielectric base to cover a first set of conductive pillars in the plurality of conductive pillars but expose a second set of conductive pillars in the plurality of conductive pillars.

2. The shielded interconnection structure of claim 1, further comprising:
a plurality of conductive bumps formed on the bottom surface of the dielectric base and electrically connected with the plurality of conductive pillars respectively.

3. The shielded interconnection structure of claim 1, wherein the first set of conductive pillars are configured for connecting with a reference voltage, and the second set of conductive pillars are configured for signal transmission.

4. The shielded interconnection structure of claim 1, wherein the plurality of conductive pillars are copper pins.

5. The shielded interconnection structure of claim 1, wherein the dielectric base comprises an epoxy molding compound.

6. A method for forming a shielded interconnection structure, comprising:
providing an interconnection strip, wherein the interconnection strip comprises a plurality of interconnection structures, and each of the plurality of interconnection structures comprises:
a dielectric base having a top surface, a bottom surface, and a lateral surface extending between the top surface and the bottom surface; and
a plurality of conductive pillars extending through the dielectric base;
forming a trench in the interconnection strip to singulate the plurality of interconnection structures; and
forming a shielding layer on each of the plurality of interconnection structures, wherein the shielding layer having a lateral portion and a top portion formed as a whole, the lateral portion of the shielding layer is formed in the trench to cover the lateral surface of the dielectric base, and the top portion of the shielding layer is formed on the top surface of the dielectric base to cover a first set of conductive pillars in the plurality of conductive pillars but expose a second set of conductive pillars in the plurality of conductive pillars.

7. The method of claim 6, wherein forming the shielding layer on each of the plurality of interconnection structures comprises:
depositing a shielding material on the interconnection strip to cover the lateral surface and the top surface of the dielectric base; and
removing a portion of the shielding material on the top surface of the dielectric base to expose the second set of conductive pillars.

8. The method of claim 7, wherein a laser ablation process is employed to remove the portion of the shielding material.

9. The method of claim 6, wherein forming the shielding layer on each of the plurality of interconnection structures comprises:
forming a patterned mask on the top surface of the dielectric base to cover the second set of conductive pillars;
depositing a shielding material on the interconnection strip to form the shielding layer; and
removing the patterned mask to expose the second set of conductive pillars.

10. The method of claim 6, wherein providing the interconnection strip comprises:
providing a first carrier;
attaching multiple conductive pillars on the first carrier via a first adhesive film; and
encapsulating the multiple conductive pillars with a molding material to form the dielectric base.

11. The method of claim 10, further comprising:
forming multiple conductive bumps on a bottom surface of the interconnection strip to electrically connect with the multiple conductive pillars respectively.

12. The method of claim 11, wherein before forming the trench in the interconnection strip, the method further comprises:
attaching the bottom surface of the interconnection strip to a second carrier via a second adhesive film; and
removing the first carrier to expose a top surface of the interconnection strip.

13. The method of claim 12, wherein after forming the shielding layer on each of the plurality of interconnection structures, the method further comprises:
detaching the plurality of interconnection structures from the second carrier.

14. The method of claim 6, wherein the first set of conductive pillars are configured for connecting with a reference voltage, and the second set of conductive pillars are configured for signal transmission.

15. The method of claim 6, wherein the plurality of conductive pillars are copper pins, and the dielectric base comprises an epoxy molding compound.

16. A semiconductor package, comprising:
a first substrate;
a second substrate disposed above the first substrate;
at least one shielded interconnection structure mounted between the first substrate and the second substrate, wherein the shielded interconnection structure comprises:
a dielectric base having a top surface, a bottom surface, and a lateral surface extending between the top surface and the bottom surface;
a plurality of conductive pillars extending through the dielectric base; and
a shielding layer having a lateral portion and a top portion formed as a whole, wherein the lateral portion of the shielding layer covers the lateral surface of the dielectric base, and the top portion of the shielding layer is formed on the top surface of the dielectric base to cover a first set of conductive pillars in the plurality of conductive pillars but expose a second set of conductive pillars in the plurality of conductive pillars,
wherein the first substrate and the second substrate are electrically connected with each other via the plurality of conductive pillars in the shielded interconnection structure.

17. The semiconductor package of claim 16, wherein the first set of conductive pillars are configured for connecting with a reference voltage, and the second set of conductive pillars are configured for signal transmission.

18. The semiconductor package of claim 16, further comprising:
at least one first electronic component mounted on a top surface of the first substrate;
a first encapsulant form on the top surface of the first substrate and encapsulating the first electronic component and the shielded interconnection structure;
at least one second electronic component mounted on a top surface of the second substrate;
a second encapsulant form on the top surface of the second substrate and encapsulating the second electronic component; and
a plurality of solder bumps formed on a bottom surface of the first substrate.

19. The semiconductor package of claim 18, wherein the first electronic component comprises an ultra-wide bandwidth integrated circuit, the second electronic component comprises a wireless communication device, and the wireless communication device is electrically connected with the shielded interconnection structure.

20. The semiconductor package of claim 18, further comprising:
an outer shielding layer covering lateral surfaces of the first substrate, the first encapsulant, the second substrate and the second encapsulant, and a top surface of the second encapsulant.
